(19) United States
(12) Patent Application Publication
(10) Pub. No.: US 2003/0045008 A1
(43) Pub. Date: Mar. 6, 2003

(54) Method and apparatus for monitoring changes in the surface of a workpiece during processing

(76) Inventors: Gregory Olsen, Tempe, AZ (US); Matthew Weldon, Phoenix, AZ (US)

Correspondence Address: SNELL & WILMER, ONE ARIZONA CENTER, 400 EAST VAN BUREN, PHOENIX, AZ, 850040001

(21) Appl. No.: 09/943,963

(22) Filed: Aug. 31, 2001

(51) Int. Cl. G01R 31/26; H01L 21/66; C23F 1/00

(52) U.S. Cl. 438/7; 438/16; 156/345.13

(57) ABSTRACT

An apparatus for monitoring changes in the surface of a wafer during processing of the wafer is provided. The apparatus includes an optical transmission assembly configured to transmit to an area of the wafer a number of first discrete bands of transmitted light. Each of said number of first discrete bands of transmitted light has an effective wavelength. The apparatus also includes an optical detection assembly configured to receive a number of discrete bands of reflected light reflected from the area of the wafer. The optical detection assembly is further configured to detect a reflected intensity of each of the number of discrete bands of reflected light. An analyzer is configured to receive from the optical detection assembly the reflected intensity of each of the number of discrete bands of reflected light and is configured to detect changes in the surface of the wafer during processing from the reflected intensity.

### FIELD OF THE INVENTION

The present invention generally relates to processing a surface of a workpiece. More particularly, the invention relates to methods and apparatus for monitoring changes in the surface of a workpiece during processing.

### BACKGROUND OF THE INVENTION

Chemical mechanical polishing or planarizing a surface of an object may be desirable for several reasons. For example, chemical mechanical polishing is often used in the formation of microelectronic devices to provide a substantially smooth, is planar surface suitable for subsequent fabrication processes such as photoresist coating and pattern definition. Chemical mechanical polishing may also be used to form microelectronic features. For example, a conductive feature such as a metal line or a conductive plug may be formed on a surface of a wafer by forming trenches and vias on the wafer surface, depositing conductive material over the wafer surface and into the trenches and vias, and removing the conductive material on the surface of the wafer using chemical mechanical polishing, leaving the vias and trenches filled with the conductive material.

A typical chemical mechanical polishing apparatus suitable for planarizing the semiconductor surface generally includes a wafer carrier configured to support, guide, and apply pressure to a wafer during the polishing process; a polishing compound such as a slurry containing abrasive particles and chemicals to assist removal of material from the surface of the wafer; and a polishing surface such as a polishing pad. In addition, the polishing apparatus may include an integrated wafer cleaning system and/or an automated load and unload station to facilitate automatic processing of the wafers.

A wafer surface is generally polished by moving the surface of the wafer to be polished relative to the polishing surface in the presence of the polishing compound. In particular, the wafer is placed in the carrier such that the surface to be polished is placed in contact with the polishing surface and the polishing surface and the wafer are moved relative to each other while slurry is supplied to the polishing surface. Following the planarization or polishing process, the wafer may also be subjected to a buffing process which further smoothes the surface of the wafer.

During a processing procedure, it is desirable to gather data on the condition of the wafer's surface. The data may then be used to optimize the process or to determine when the process should be terminated (referred to as the “endpoint”). It is generally preferred that endpoint detection (EPD) systems be in-situ systems to provide monitoring during processing. Numerous in-situ EPD systems have been proposed, but few have been successful in a manufacturing environment and even fewer are sufficiently robust for routine production use.

Accordingly, there is a need for an in in-situ system that could quickly and accurately monitor changes in the surface of a wafer. In addition, there is a need for an in-situ system that could monitor changes in the surface of a wafer during a variety of processing procedures.

### SUMMARY OF THE INVENTION

This summary of the invention section is intended to introduce the reader to aspects of the invention and is not a complete description of the invention. Particular aspects of the invention are pointed out in other sections hereinbelow, and the invention is set forth in the appended claims which alone demarcate its scope.

In accordance with an exemplary embodiment of the present invention, an apparatus for monitoring changes in the surface of a wafer during processing of the wafer is provided. The apparatus includes an optical transmission assembly configured to transmit to an area of the wafer a number of first discrete bands of transmitted light. Each of said number of first discrete bands of transmitted light has an effective wavelength. The apparatus also includes an optical detection assembly configured to receive a number of discrete bands of reflected light reflected from the area of the wafer. The optical detection assembly is further configured to detect a reflected intensity of each of the number of first discrete bands of reflected light. An analyzer is configured to receive from the optical detection assembly the reflected intensity of each of the number of first discrete bands of reflected light and is configured to detect changes in the surface of the wafer during processing from the reflected intensity.

In another embodiment of the invention, a method for monitoring the changes in the surface of a wafer during processing of the wafer is provided. The method includes transmitting to an area of the wafer a number of first discrete bands of transmitted light. Each of the number of first discrete bands of transmitted light has a different effective wavelength. The method also includes receiving a number of discrete bands of reflected light reflected from the area of the wafer. Each of the discrete bands of reflected light has a reflected intensity. The reflected intensity for each of the number of discrete bands of reflected light is detected and the reflected intensity for each of the number of discrete bands of reflected light is analyzed to detect changes in the surface of the wafer during processing.

In a further embodiment of the invention, a system for monitoring changes in the surface of a wafer during processing of the wafer is provided. The system includes a polishing assembly and a wafer carrier configured to press the wafer against the polishing assembly. An optical probe is positioned within the polishing assembly and is in operative communication with a light source. The light source is configured to transmit to an area of the wafer, via the optical probe, a number of first discrete bands of transmitted light. Each of the number of first discrete bands of transmitted light has an effective wavelength. An optical detector is also in operative communication with the optical probe. The optical detector is configured to receive, via the optical probe, a number of first bands of reflected light reflected form the area of the wafer. The optical detector is further configured to detect a reflected intensity of each of the number of first discrete bands of reflected light. An analyzer is configured to receive from the optical detector the reflected intensity of each of the number of first discrete bands of reflected light and is configured to detect changes in the surface of the wafer during processing from the reflected intensities.

### BRIEF DESCRIPTION OF THE DRAWINGS

A more complete understanding of the present invention may be derived by referring to the detailed description and claims, considered in connection with the figures, wherein like reference numbers refer to similar elements throughout the figures, and:

FIG. 1 illustrates a top cut-away view of a polishing system in accordance with the present invention;

FIG. 2 illustrates a top cut-away view of a polishing system in accordance with another embodiment of the invention;

FIG. 3 illustrates a bottom view of a carrier carousel for use with the apparatus illustrated in FIG. 2;

FIG. 4 illustrates a top cut-away view of a polishing system in accordance with yet another embodiment of the invention;

FIG. 5 illustrates a bottom view of a carrier for use with the system of FIG. 4;

FIG. 6 is a schematic representation of an apparatus using an endpoint detection system in accordance with an embodiment of the present invention; and

FIG. 7 is a graph of the effective wavelengths of a number of discrete bands of light versus intensity.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DESCRIPTION OF EXEMPLARY EMBODIMENTS

The following description is of exemplary embodiments only and is not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

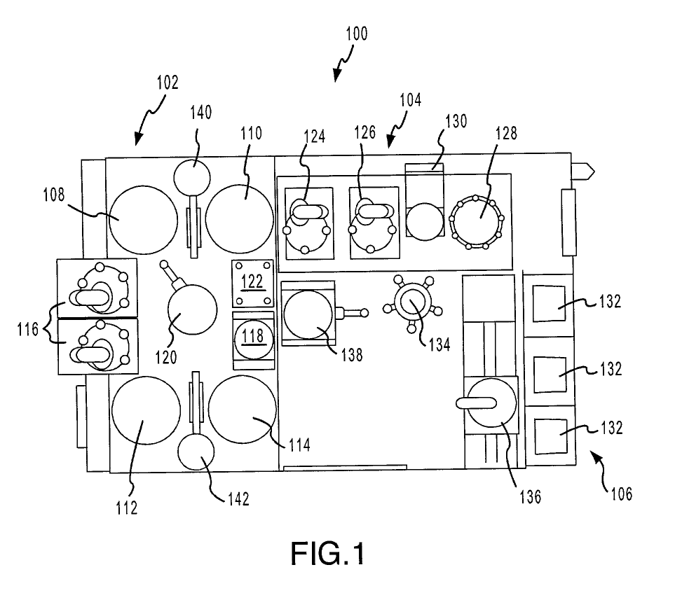

FIG. 1 illustrates a top cut-way view of a processing apparatus 100, suitable for removing material from or polishing material on a surface of a workpiece, in accordance with the present invention. Apparatus 100 includes a multi-platen polishing system 102, a clean system 104, and a wafer load and unload station 106. In addition, apparatus 100 includes a cover (not illustrated) that surrounds apparatus 100 to isolate apparatus 100 from the surrounding environment. In accordance with a preferred embodiment of the present invention, machine 100 is a Momentum machine available from SpeedFam-IPEC Corporation of Chandler, Ariz. However, machine 100 may be any machine capable of polishing or removing material from a workpiece surface.

Although the present invention may be used to remove or polish material from a surface of a variety of workpieces such as magnetic discs, optical discs, and the like, the invention is conveniently described below in connection with removing material from or polishing material on a surface of a wafer. In the context of the present invention, the term “wafer” shall mean semiconductor substrates, which may include layers of insulating, semiconducting, and conducting layers or features formed thereon, used to manufacture microelectronic devices.

Exemplary polishing system 102 includes four polishing stations 108, 110, 112, and 114, which each operate independently; a buff station 116; a transition stage 118; a robot 120; and optionally, a metrology station 122. Polishing stations 108-114 may be configured as desired to perform specific functions. For example one or more of polishing stations 108-114 may be configured for orbital, rotational and/or linear motion. The polishing stations may be configured for chemical mechanical polishing, electrochemical polishing, electrochemical deposition, or the like.

Polishing system 102 also includes polishing surface conditioners 140,142. The configuration of conditioners 140,142 generally depends on the type of polishing surface to be conditioned. For example, when the polishing surface comprises a polyurethane polishing pad, conditioners 140,142 suitably include a rigid substrate coated with diamond material. Various other surface conditioners may also be used in accordance with the present invention.

Clean system 104 is generally configured to remove debris such as slurry residue and material removed from the wafer surface during polishing. In accordance with the illustrated embodiment, system 104 includes clean stations 124 and 126, a spin rinse dryer 128, and a robot 130 configured to transport the wafer between clean stations 124,126 and spin rinse dryer 128. In accordance with one aspect of this embodiment, each clean station 124 and 126 includes two concentric circular brushes, which contact the top and bottom surfaces of a wafer during a clean process.

Wafer load and unload station 106 is configured to receive dry wafers for processing in cassettes 132. In accordance with the present invention, the wafers are dry when loaded onto station 106 and are dry before return to station 106.

In accordance with an alternate embodiment of the invention, clean system 104 may be separate from the polishing apparatus. In this case, load station 106 is configured to receive dry wafers for processing, and the wafers are held in a wet (e.g., deionized water) environment until the wafers are transferred to the clean station.

In operation, cassettes 132, including one or more wafers, are loaded onto apparatus 100 at station 106. A wafer from one of cassettes 132 is transported to a stage 134 using a dry robot 136. A wet robot 138 retrieves the wafer at stage 134 and transports the wafer to metrology station 122 for film characterization or to stage 118 within polishing system 102. In this context, a “wet robot” means automation equipment configured to transport wafers that have been exposed to a liquid or that may have liquid remaining on the wafer and a “dry robot” means automation equipment configured to transport wafers that are substantially dry. Robot 120 picks up the wafer from metrology station 122 or stage 118 and transports the wafer to one of polishing stations 108-114 for processing.

After processing, the wafer is transferred to buff station 116 to further polish the surface of the wafer. The wafer is then transferred (optionally to metrology station 122 and) to stage 118, which keeps the wafers in a wet environment, for pickup by robot 138. Once the wafer is removed from the polishing surface, conditioners 140,142 may be employed to condition the polishing surface. Conditioners 140, 142 may also be employed prior to polishing a wafer to prepare the surface for wafer polishing.

After a wafer is placed in stage 118, robot 138 picks up the wafer and transports the wafer to clean system 104. In particular, robot 138 transports the wafer to robot 130, which in turn places the wafer in one of clean stations 124,126. The wafer is cleaned using one or more stations 124, 126 and is then transported to spin rinse dryer 128 to rinse and dry the wafer prior to transporting the wafer to load and unload station 106 using robot 136.

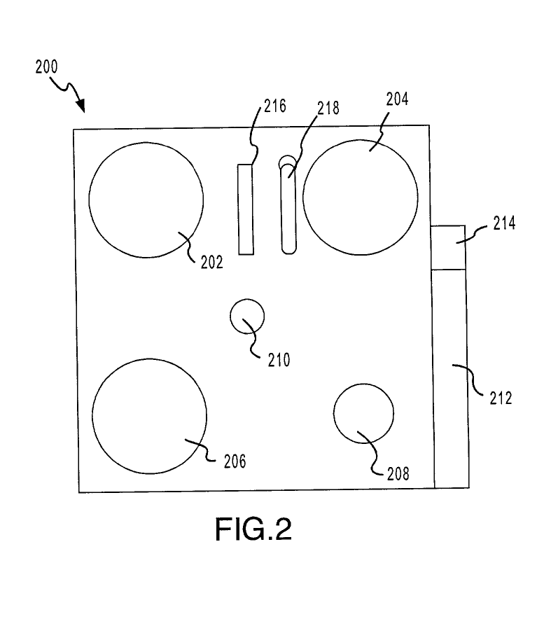

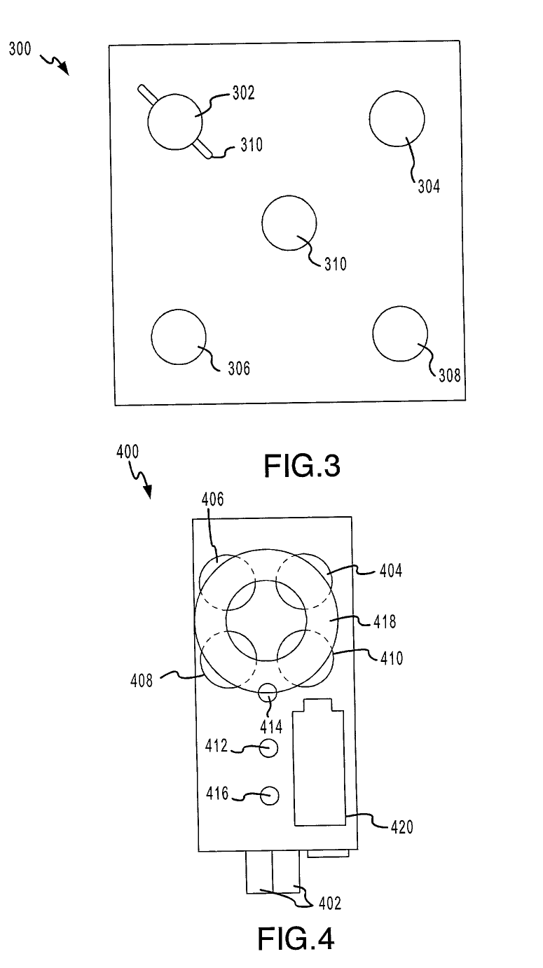

FIG. 2 illustrates a top cut-away view of another exemplary polishing apparatus 200, configured to remove material from or polish material on a wafer surface. Apparatus 200 is suitably coupled to carousel 300, illustrated in FIG. 3, to form an automated processing system. A processing system in accordance with this embodiment may also include a removable cover (not illustrated in the figures) overlying apparatus 200 and 300.

Apparatus 200 includes three polishing stations 202, 204, and 206, a wafer transfer station 208, a center rotational post 210, which is coupled to carousel 300, and which operatively engages carousel 300 to cause carousel 300 to rotate, a load and unload station 212, and a robot 214 configured to transport wafers between stations 212 and 208. Furthermore, apparatus 200 may include one or more rinse washing stations 216 to rinse and/or wash a surface of a wafer before or after a polishing process and one or more pad conditioners 218. Although illustrated with three polishing stations, apparatus 200 may include any desired number of polishing stations and one or more of such polishing stations may be used to buff a surface of a wafer as described herein. Furthermore, apparatus 200 may include an integrated wafer clean and dry system similar to system 104 described above.

Wafer transfer station 208 is generally configured to stage wafers before or between polishing processes and to load and unload wafers from wafer carriers described below. In addition, station 208 may be configured to perform additional functions such as washing the wafers and/or maintaining the wafers in a wet environment.

Carousel apparatus 300 includes wafer carriers 302, 304, 306, and 308, each configured to hold a single wafer. In accordance with one embodiment of the invention, three of carriers 302-308 are configured to retain and urge the wafer against a polishing surface (e.g., a polishing surface associated with one of stations 202-206) and one of carriers 302-308 is configured to transfer a wafer between a polishing station and stage 208. Each carrier 302-308 is suitably spaced from post 210, such that each carrier aligns with a polishing station or station 208. In accordance with one embodiment of the invention, each carrier 302-308 is attached to a rotatable drive mechanism using a gimbal system (not illustrated), which allows carriers 302-308 to cause a wafer to rotate (e.g., during a polishing process). In addition, the carriers may be attached to a carrier motor assembly that is configured to cause the carriers to translate—e.g., along tracks 310. In accordance with one aspect of this embodiment, each carrier 302-308 rotates and translates independently of the other carriers.

In operation, wafers are processed using apparatus 200 and 300 by loading a wafer onto station 208, from station 212, using robot 214. One of carriers 302-308 is rotated above station 208 and descends towards station 208 to remove the wafer from station 208. Station 208 is then reloaded with a wafer. Carousel 300 is then rotated to position an unloaded carrier above station 208. The unloaded carrier descends towards station 208 to remove the wafer from station 208. The process continues until a desired number of wafers are loaded onto the carriers. When a desired number of wafers are loaded onto the carriers, at least one of the wafers is placed in contact with a polishing surface. The wafer may be positioned by lowering a carrier to place the wafer surface in contact with the polishing surface or a portion of the carrier (e.g., a wafer holding surface) may be lowered, to position the wafer in contact with the polishing surface. After polishing is complete, one or more conditioners—e.g., conditioner 218, may be employed to condition the polishing surfaces.

FIG. 4 illustrates another polishing system 400 in accordance with the present invention. System 400 is suitably configured to receive a wafer from a cassette 402 and return the wafer to the same or to a predetermined different location within a cassette in a clean, dry state.

System 400 includes polishing stations 404 and 406, a buff station 408, a head loading station 410, a transfer station 412, a wet robot 414, a dry robot 416, a rotatable index table 418, and a clean station 420.

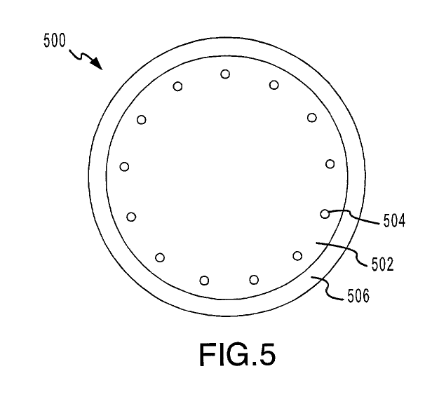

During a polishing process, a wafer is held in place by a carrier 500, illustrate in FIG. 5. Carrier 500 includes a receiving plate 502, including one or more apertures 504, and a retaining ring 506. Apertures 504 are designed to assist retention of a wafer by carrier 500 by, for example, allowing a vacuum pressure to be applied to a back side of the wafer or by creating enough surface tension to retain the wafer. Retaining ring limits the movement of the wafer during the polishing process.

In operation, dry robot 416 unloads a wafer from a cassette 402 and places the wafer on transfer station 412. Wet robot 414 retrieves the wafer from station 412 and places the wafer on loading station 410. The wafer then travels to polishing stations 404-408 for polishing and returns to station 410 for unloading by robot 414 to station 412. The wafer is then transferred to clean system 420 to clean, rinse, and dry the wafer before the wafer is returned to load and unload station 402 using dry robot 416.

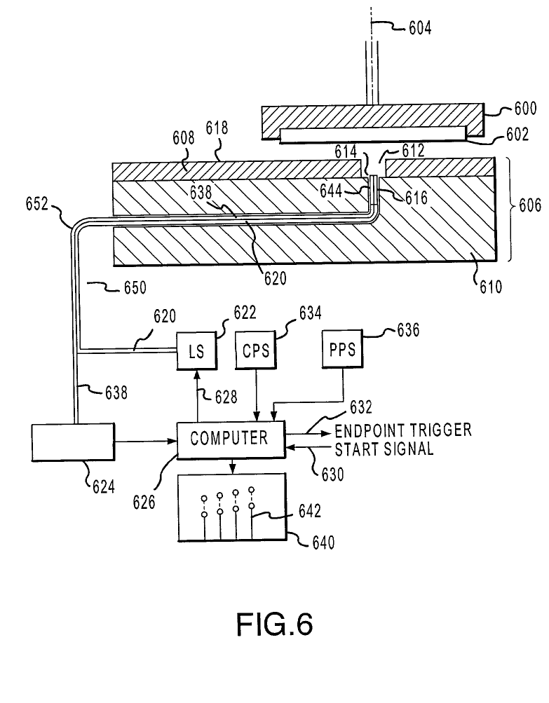

Each of the above processing systems may utilize an endpoint detection (EPD) system that is configured to monitor the surface of a wafer that is being subjected to planarization, polishing, buffing or other processing procedures. A schematic representation of an embodiment of an endpoint detection system of the present invention is illustrated in FIG. 6. A wafer carrier 600, such as any of the wafer carriers described above, holds a wafer 602 that is to be polished, planarized, buffed or otherwise processed. The wafer carrier preferably rotates about its vertical axis 604 but may also move in an orbital or linear motion. A polishing assembly 606, such as any of the polishing stations described above, is formed of a polishing pad 608 and a platen 610. Polishing pad 608 is mounted to platen 610, which is secured to a driver or motor assembly (not shown) that is operative to move the polishing pad 608 in an orbital, rotational and/or linear motion. Polishing pad 608 includes a through-hole 612 that is coincident and communicates with an opening 614 in the platen 610. The EPD system of the present invention includes an optical transmission assembly 650, an optical detection assembly 652 and an analyzer 626.

Optical transmission assembly 650 includes at least one optical probe 616 that is inserted through a bore in platen 610 and through through-hole 612 so that the distal tip of the probe is flush or slightly below a polishing surface 618 of polishing pad 608. While optical probe 616 is illustrated in FIG. 6 positioned in a bore in platen 610, it will be appreciated that optical probe 616 may be positioned in polishing assembly 606 in any suitable manner that will permit optical probe 616 to transmit light to wafer 602. Optical transmission assembly 650 also includes a light source 622, which is in operative communication with optical probe 616 via a fiber optic cable 620. Analyzer 626 provides a control signal 628 to light source 622 that directs the emission of light from the light source 622. Analyzer 626 also receives a start signal that will activate the light source 622 and the EPD methodology. The analyzer provides an endpoint trigger 632 when it is determined that the endpoint of the processing has been reached.

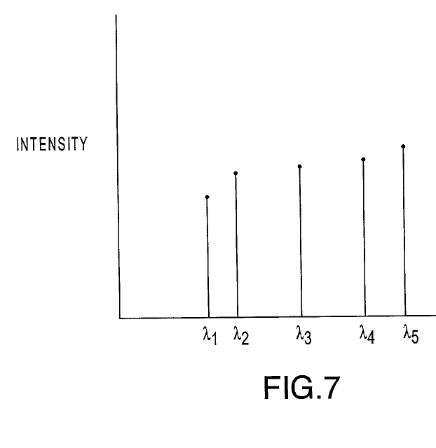

Light source 622 is configured to emit pulses of a number of discrete bands of light, each discrete band having one effective wavelength. FIG. 7 is a graph that illustrates a pulse of a number of discrete bands of light that is emitted from light source 622 in accordance with an exemplary embodiment of the present invention. Each pulse includes a finite number of light bands, each with an effective wavelength. For example, each pulse of light emitted from light source 622 may have 5,10, 20, or any other suitable finite number of discrete bands of light. Each band may be light having one wavelength, or, alternatively, may be formed of a continuous band of light that is sufficiently narrow that the band has one “effective” wavelength. By the term “effective” wavelength, it is meant an average, mean or other representative wavelength of the band of light. For example, as illustrated in FIG. 7, light source 622 may emit a pulse formed of 5 discrete bands of light that have the effective wavelengths of λ₁, λ₂, λ₃, λ₄ and λ₅, respectively. By having one effective wavelength, the discrete band of light may be detected by a sensor that is configured to receive light of only one wavelength, as described in more detail below. Preferably, the effective wavelengths of the discrete bands of light emitted by light source 622 fall within a range of from about 200 nm to about 1200 nm. In one exemplary embodiment of the invention, light source 622 is configured to emit the number of discrete bands of light simultaneously. In another exemplary embodiment of the invention, light source 622 is configured to emit the number of discrete bands of light in succession.

In a further exemplary embodiment of the invention, light source 622 is configured to emit a pulse of the number of discrete bands of light, the bands being transmitted either simultaneously or successively, over a short time period compared to the movement of the wafer by wafer carrier 600 relative to the motion of polishing assembly 606. Because typically the wafer carrier and/or the polishing assembly move during processing, the optical probe scans different areas of the wafer. However, according to an embodiment of the present invention, a pulse of the discrete bands of light is transmitted to the wafer in a very short period of time relative to movement of the wafer. Accordingly, a pulse of the number of discrete bands is transmitted to the same area of the wafer before the wafer moves relative to the optical probe. In this manner, a desired number of data points corresponding to the surface of the wafer at a given area can be obtained in a short period of time. Further, because the pulse of the discrete bands of light is transmitted to the wafer in such a short period of time relative to the movement of the wafer, a greater number of data points on the surface of the wafer may be obtained.

In one exemplary embodiment of the invention, light source 622 may comprise a laser system, or a plurality of laser systems, suitably configured so that a number of discrete bands of light, each having an effective wavelength, may be transmitted through fiber optical cable 620 to optical probe 616 to illuminate an area on wafer 602. For example, light source 622 may be an ultrashort-pulse laser that utilizes a tuning aperatures. Ultrashort-pulse lasers emit pulses of light having a large range of wavelengths. A tuning aperature or aperatures may be used with an ultrashort-pulse laser to emit discrete bands of light, each having a different effective wavelength. Ultrashort-pulse lasers are capable of emitting pulses of coherent light in on the order of femtoseconds. It will be appreciated, however, that light source 622 may include any suitable light source that is configured to emit a number of discrete bands of light, each having an effective wavelength.

In another embodiment of the invention, referring again to FIG. 6, the endpoint detection system of the present invention also includes a polishing assembly position sensor 636 that provides the position of the polishing assembly to analyzer 626. In a further embodiment of the invention, the endpoint detection system of the present invention also includes a wafer carrier's position sensor 634 that provides the position of the wafer carrier to analyzer 626. Analyzer 626 can synchronize the trigger of the data collection to the positional information from the sensors.

In operation, soon after the processing procedure has begun, the start signal 630 is provided to the analyzer 626 to initiate the monitoring process. Analyzer 626 then directs light source 622 to transmit pulses of a number of discrete bands of light from the light source 622 via fiber optic cable 620 to be incident on the surface of the wafer 602 through opening 614 and the through-hole 612 in the polishing pad 608. Light source 622 may transmit the bands of light either simultaneously or successively. Each band of light has an effective wavelength and a transmitted intensity. The pulses of light are transmitted to the surface of the wafer in a time period of sufficiently short duration that the wafer effectively appears stationary during transmission of the number of pulses of light.

Optical detection assembly 652 includes at least one optical probe 644 that is inserted through a bore in platen 610 and through through-hole 612 so that the distal tip of the probe is flush or slightly below polishing surface 618 of polishing paid 608. While optical probe 618 is illustrated in FIG. 6 positioned in a bore in platen 610, it will be appreciate that optical probe 618 may be positioned in polishing assembly 606 in any suitable manner that will permit optical probe 618 to receive light reflected from wafer 602. In addition, while FIG. 6 illustrates optical probes 616 and 618 as separate probes, it will be appreciated that one probe suitably configured to transmit light to and receive light reflected from wafer 601 may be used.

Optical detection assembly 652 also includes an optical detector 624. Reflected pulses of light from the surface of the wafer 602 are captured by optical probe 618 and are routed to optical detector 624 via a fiber optic cable 638. Optical detector 624 may be formed of a plurality of sensors, each of which is configured to receive light at a given effective wavelength and to detect the reflected intensity of the light. For example, in one embodiment of the invention, optical detector 624 could be formed of a plurality of photodiodes or other suitable photodetectors. Photodetectors that are configured to receive light at one wavelength may operate more quickly than light sensors that are configured to receive a broadband of light, as the photodetectors do not need to analyze the wavelengths of the band of light. Alternatively, optical detector 624 may be formed of one sensor that is configured to detect each discrete band of reflected light and analyze the reflected intensity of each band. It will be appreciated, however, that any suitable photodetector that can accept light reflected from the surface of the wafer 602 and analyze the reflected intensity of the light may be used in the optical detection assembly of the present invention.

Although in the above-described embodiment of the present invention the reflected light is relayed using fiber optic cable 638, which is separate from fiber optic cable 620, it will be appreciated that one fiber optic cable performing the functions of cables 620 and 638 may be used. Because of the short time duration with which the pulses of the number of discrete bands of light are transmitted from light source 622 to the surface of the wafer 602, a pulse of all of the bands of light will already have been transmitted to the wafer surface and reflected back to optical probe 616 before another pulse of discrete bands of light are transmitted by light source 622. Accordingly, one fiber optic cable may be used to transmit light to and receive reflected light from the wafer surface.

Once the optical detector 624 receives a reflected light pulse and determines the reflected intensities of the discrete bands of light on the pulse, it produces electric signals corresponding to the reflected intensities and transmits the electrical signals to analyzer 626. Analyzer 626 then compares the reflected intensity signals from the optical detector to a predetermined criteria. A result of the analysis by analyzer 626 is an output signal 642 that is displayed on a monitor 640. By having to analyze only a limited number of discrete bands of light, rather than a continuous spectrum of light comprising an infinite number of wavelengths, analyzer 626 is able to quickly calculate data representing the condition of the surface of the wafer. Preferably, analyzer 626 automatically compares the reflected intensity signals to predetermined criteria to calculate an endpoint as a function of the comparison. Alternatively, an operator can monitor the output signal 642 and select an endpoint based on the operator's interpretation of the output signal 642. Once the endpoint is detected, an endpoint trigger 632 is produced to cause the processing machine to advance to the next processing step.

In another exemplary embodiment of the invention, the wavelengths and/or the number of the discrete bands of light emitted by light source 622 may be strategically selected based on the material being processed to optimize the detection of changes in the surface of wafer 602 during processing. It is well known that different materials may reflect light of a given wavelength at different intensities. For example, a wafer may have a first layer formed of a first material overlying a second layer formed of a second material. If the first layer is to be removed by polishing pad assembly 606, followed subsequently by removal of the second layer, a first set of a predetermined number of discrete bands of light, each band having a predetermined effective wavelength, may be selected based on the first layer's ability to reflect these bands of light. A second set of a predetermined number of discrete bands of light, each band having a predetermined effective wavelength, may be selected based on the second layer's ability to reflect these discrete bands of light. Light source 622 may be configured to continuously transmit pulses of the first set of discrete bands of light to the wafer to optimize detection of removal of the first layer and to continuously transmit pulses of the second set of discrete bands of light to the wafer to optimize detection of removal of the second layer. Accordingly, the EPD system is versatile, configured to monitor the condition of surfaces of a variety of materials.

In a further exemplary embodiment of the present invention, analyzer 626 may be configured to automatically transmit a different set of a number of discrete bands of light based on a detected endpoint of a procedure. Using the above example, if analyzer 626 analyzes data received from the optical detection assembly and determines that the first layer has been sufficiently removed to satisfy predetermined criteria, it may then terminate transmission of the first set of discrete bands of light and transmit the second set of discrete bands of light to detect the removal of the second layer. In turn, if analyzer 626 analyzes the date received from the optical detection assembly during the processing of the second layer and determines that the second layer has been sufficiently removed to satisfy predetermined criteria, computer 626 may detect the endpoint of processing and, accordingly, terminate processing altogether.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. An apparatus for monitoring changes in the surface of a wafer during processing of the wafer, said apparatus comprising:
an optical transmission assembly configured to transmit to an area of the wafer a number of first discrete bands of transmitted light, each of said number of first discrete bands of transmitted light having an effective wavelength;
an optical detection assembly configured to receive a number of discrete bands of reflected light reflected from said area of the wafer, said optical detection assembly further configured to detect a reflected intensity of each of said number of discrete bands of reflected light; and
an analyzer configured to receive from said optical detection assembly said reflected intensity of each of said number of discrete bands of reflected light and configured to detect changes in the surface of the wafer during processing from said reflected intensities.

2. The apparatus of claim 1, wherein each of said number of first discrete bands of transmitted light comprises light having one wavelength.

3. The apparatus of claim 1, wherein each of said number of first discrete bands of transmitted light comprises light having an average wavelength.

4. The apparatus of claim 1, wherein said optical transmission assembly comprises an ultra short pulse laser.

5. The apparatus of claim 1, wherein said optical transmission assembly is configured to transmit to said area of the wafer said number of first discrete bands of transmitted light simultaneously.

6. The apparatus of claim 1, wherein said optical transmission assembly is configured to transmit to said area of the wafer said number of first discrete bands of transmitted light in succession.

7. The apparatus of claim 1, wherein each of said number of first discrete bands of transmitted light has an effective wavelength within the range of approximately 240 nm to 1200 nm.

8. The apparatus of claim 1, wherein each of said number of first discrete bands of transmitted light are selected to optimize detection of changes in the surface of the wafer during processing.

9. The apparatus of claim 1, wherein said optical detection assembly comprises a plurality of sensors, each of said plurality of sensors configured to receive a band of light having an effective wavelength.

10. The apparatus of claim 1, wherein said analyzer is further configured to direct said optical transmission assembly to transmit to the wafer a number of second discrete bands of transmitted light when said analyzer detects a predetermined change in the surface of the wafer, each of said number of second discrete bands of transmitted light having an effective wavelength.

11. The apparatus of claim 1, wherein said number of first discrete bands of transmitted light is greater than one.

12. A method for monitoring changes in the surface of a wafer during processing of said wafer, said method comprising:
transmitting to an area of the wafer a number of first discrete bands of transmitted light, each of said number of first discrete bands of transmitted light having an effective wavelength;
receiving a number of discrete bands of reflected light reflected from said area of the wafer, each of said discrete bands of reflected light having a reflected intensity;
detecting said reflected intensity for each of said number of discrete bands of reflected light; and
analyzing said reflected intensity for each of said number of discrete bands of reflected light to detect changes in the surface of the wafer during processing.

13. The method of claim 12, further comprising:
selecting said first discrete bands of transmitted light to optimize monitoring of changes in the surface of the wafer.

14. The method of claim 12, wherein said transmitting comprises transmitting to said area of the wafer said number of first discrete bands of transmitted light simultaneously.

15. The method of claim 12, wherein said transmitting comprises transmitting to said area of the wafer said number of first discrete bands of transmitted light successively.

16. The method of claim 12, wherein each of said number of first discrete bands of transmitted light comprises light having one wavelength.

17. The method of claim 12, wherein each of said number of first discrete bands of transmitted light comprises light having an average wavelength.

18. The method of claim 12, further comprising:
upon detecting a predetermined change in the surface of the wafer, transmitting to the wafer a number of second discrete bands of transmitted light, each of said number of second discrete bands of transmitted light having an effective wavelength.

19. The method of claim 12, wherein said number of first discrete bands of transmitted light is greater than one.

20. A system for monitoring changes in the surface of a wafer during processing of the wafer, said system comprising:
a polishing assembly;
a wafer carrier configured to press the wafer against said polishing assembly;
an optical probe positioned within said polishing assembly;
a light source in operative communication with said optical probe, said light source configured to transmit to an area of the wafer, via said optical probe, a number of first discrete bands of transmitted light, each of said number of first discrete bands of transmitted light having an effective wavelength, wherein said number of first discrete bands of transmitted light is greater than one;
an optical detector in operative communication with said optical probe, said optical detector configured to receive, via said optical probe, a number of bands of reflected light reflected from said area of the wafer, said optical detector further configured to detect a reflected intensity of each of said number of discrete bands of reflected light; and
an analyzer configured to receive from said optical detector said reflected intensity of each of said number of discrete bands of reflected light and configured to detect changes in the surface of the wafer during processing from said reflected intensities.

21. The system of claim 20, wherein said polishing assembly is configured to move in at least one of an orbital, rotational and linear motion.

22. The system of claim 20, wherein said wafer carrier is configured to move in at least one of an orbital, rotational and linear motion.

23. The system of claim 20, wherein each of said number of first discrete bands of transmitted light comprises light having one wavelength.

24. The system of claim 20, wherein each of said number of first discrete bands of transmitted light comprises light having an average wavelength.

25. The system of claim 20, wherein said light source comprises an ultra short pulse laser.

26. The system of claim 20, wherein said light source is configured to transmit to said area of the wafer said number of first discrete bands of transmitted light simultaneously.

27. The system of claim 20, wherein said light source is configured to transmit to said area of the wafer said number of first discrete bands of transmitted light successively.

28. The system of claim 20, wherein each of said number of first discrete bands of transmitted light has an effective wavelength within the range of approximately 240 nm to 1200 nm.

29. The system of claim 20, wherein each of said number of first discrete bands of transmitted light are selected to optimize detection of changes in the surface of the wafer during processing.

30. The system of claim 20, wherein said optical detector comprises a plurality of sensors, each of said plurality of sensors configured to receive a band of light having an effective wavelength.

31. The system of claim 20, wherein said analyzer is further configured to direct said light source to transmit to the wafer a number of second discrete bands of transmitted light when said analyzer detects a predetermined change in the surface of the wafer, each of said number of second discrete bands of transmitted light having an effective wavelength, wherein said number of second discrete bands of transmitted light is greater than one.
